(19) United States
(12) Patent Application Publication
(10) Pub. No.: US 2025/0323231 A1
(43) Pub. Date: Oct. 16, 2025

(54) ADAPTABLE MEMORY SYSTEM WITH MULTIPLE CHIPLETS

(71) Applicant: Western Digital Technologies, Inc., San Jose, CA (US)

(72) Inventors: Chengqing Hu, Milpitas, CA (US); Henry Chin, Fremont, CA (US); Deepanshu Dutta, Fremont, CA (US); Changyuan Chen, San Ramon, CA (US); Zhixin Cui, Fremont, CA (US); Swaroop Kaza, Milpitas, CA (US)

(73) Assignee: Western Digital Technologies, Inc., San Jose, CA (US)

(21) Appl. No.: 18/631,140

(22) Filed: Apr. 10, 2024

(51) Int. Cl. H01L 25/18; H01L 23/00; H10B 80/00

(52) U.S. Cl. CPC H01L 25/18; H01L 24/08; H01L 24/80; H01L 24/94; H10B 80/00; H01L 2224/08147; H01L 2224/80895; H01L 2224/94; H01L 2924/1431; H01L 2924/1438

(57) ABSTRACT

An apparatus includes a silicon wafer and a plurality of memory dies. The silicon wafer includes a plurality of control dies, each control die having first bond pads on a first surface. The plurality of memory dies each have second bond pads on a second surface facing the first surface of the control die. The second bond pads of each memory die are bonded to corresponding first bond pads on the first surface of the memory control circuit.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power (e.g., a battery).

One type of non-volatile memory has strings of non-volatile memory cells that have a select transistor at each end of the string. Typically, such strings are referred to as NAND strings and non-volatile memory chips or dies in which such NAND strings are formed may be referred to as NAND chips or dies.

In some examples, a silicon wafer that includes multiple non-volatile memory dies (e.g., NAND dies) may be bonded to another silicon wafer that includes an equal number of dies that include logic circuits (e.g., control dies, logic dies or Application Specific Integrated Circuits (ASICs)). Bonded wafers are then scribed (divided) into individual assemblies (integrated memory assemblies) that each include a memory die and a control die. Because a defect in either the memory die or the control die in such an arrangement may result in a failed integrated memory assembly, failure rates may be undesirably high.

### BRIEF DESCRIPTION OF THE DRAWINGS

Like-numbered elements refer to common components in the different figures.

FIG. 1 (FIG. 1) is a functional block diagram of a memory device.

FIGS. 2A-B are block diagrams depicting embodiments of a memory system.

FIG. 3 is a perspective view of a portion of one embodiment of a monolithic three dimensional memory structure.

FIGS. 4A-C show an example of a nonvolatile memory structure.

FIG. 5 shows an example of wafer-to-wafer bonding.

FIGS. 6A-B illustrate an example of die-to-wafer bonding to form an integrated memory assembly.

FIGS. 7A-B illustrate another example of die-to-wafer bonding to form an integrated memory assembly.

FIGS. 8A-B illustrate another example of die-to-wafer bonding to form an integrated memory assembly.

FIGS. 9A-B illustrate another example of die-to-wafer bonding to form an integrated memory assembly.

FIGS. 10A-B illustrate another example of die-to-wafer bonding to form an integrated memory assembly.

FIGS. 11A-B illustrate examples of bond pads of a slot on a control die and corresponding bond pads on a memory chiplet respectively.

FIG. 12 illustrates an example of an integrated memory assembly.

FIG. 13 illustrates an example of probe pads formed in scribe areas between memory chiplets in a silicon wafer.

FIGS. 14A-D illustrate an example of scribing a silicon wafer to separate individual memory chiplets.

FIG. 15 illustrates an example of manufacturing integrated memory assemblies using die-to-wafer bonding.

FIG. 16 illustrates an example of a method that includes bonding memory die to a control die located in a silicon wafer.

FIG. 17 illustrates a method that includes determining control dies are defective/not defective.

### DETAILED DESCRIPTION

Techniques are provided for making integrated memory assemblies in a manner that produces relatively few defective assemblies and has a high degree of configurability (e.g., integrated memory assemblies can easily be configured with different capacities and/or characteristics). An example of the present technology includes bonding memory dies or chiplets individually to a memory control circuit wafer in what may be referred to as die-to-wafer bonding. In contrast with wafer-to-wafer bonding, in which opposing dies of entire wafers are aligned and bonded, die-to-wafer bonding allows the number of memory dies and the characteristics of the individual memory dies to be selected (e.g., only non-defective memory dies having appropriate capacities). A control die may have multiple slots, each configured to interface with a memory chiplet. Some or all slots may be occupied by memory chiplets that may be identical or may have different characteristics to give a high degree of configurability.

Testing of memory chiplets prior to die-to-wafer bonding may ensure that only non-defective memory chiplets are used so that no good control dies are wasted as a result of bonding with defective memory chiplets. Testing of memory chiplets may include probing using probe pads provided on a surface of a memory wafer. For example, such probe pads may be located in scribe areas of a memory wafer so that probe pads can be provided without adding to memory die area (e.g., probe pads only occupy space in scribe areas that are removed during scribing, prior to die-to-wafer bonding).

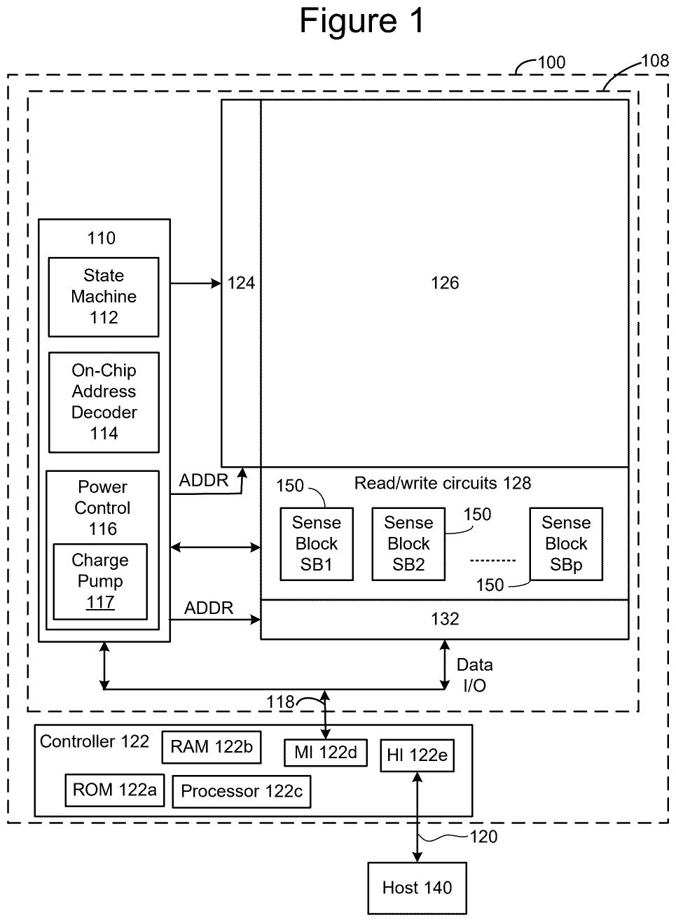

FIG. 1 is a functional block diagram of an example memory system 100. The components depicted in FIG. 1 are electrical circuits. Memory system 100 includes one or more memory dies 108. The one or more memory dies 108 can be complete memory dies or partial memory dies. In one embodiment, each memory die 108 includes a memory structure 126, control circuit 110, and read/write circuits 128. Memory structure 126 is addressable by word lines via a row decoder 124 and by bit lines via a column decoder 132. The read/write/erase circuits 128 include multiple sense blocks 150 including SB1, SB2, . . . , SBp (sensing circuits) and allow a page of memory cells to be read or programmed in parallel. Also, many strings of memory cells can be erased in parallel.

In some systems, a controller 122 is included in the same package (e.g., a removable storage card) as the one or more memory die 108. However, in other systems, the controller can be separated from the memory die 108. In some embodiments the controller will be on a different die than the memory die 108. In some embodiments, one controller 122 will communicate with multiple memory die 108. In other embodiments, each memory die 108 has its own controller. Commands and data are transferred between a host 140 and controller 122 via a data bus 120, and between controller 122 and the one or more memory die 108 via lines 118. In one embodiment, memory die 108 includes a set of input and/or output (I/O) pins that connect to lines 118.

Control circuit 110 cooperates with the read/write circuits 128 to perform memory operations (e.g., write, read, erase and others) on memory structure 126, and includes state machine 112, an on-chip address decoder 114, and a power control circuit 116. In one embodiment, control circuit 110 includes buffers such as registers, ROM fuses and other storage devices for storing default values such as base voltages and other parameters.

The on-chip address decoder 114 provides an address interface between addresses used by host 140 or controller 122 to the hardware address used by the decoders 124 and 132. Power control circuit 116 controls the power and voltages supplied to the word lines, bit lines, and select lines during memory operations. The power control circuit 116 includes voltage circuitry, in one embodiment. Power control circuit 116 includes charge pumps 117 for creating voltages. The sense blocks include bit line drivers. The power control circuit 116 executes under control of the state machine 112, in one embodiment.

State machine 112 and/or controller 122 (or equivalently functioned circuits), in combination with all or a subset of the other circuits depicted in FIG. 1, can be considered a control circuit that performs various functions described herein. The control circuit can include hardware only or a combination of hardware and software (including firmware). For example, a controller programmed by firmware to perform the functions described herein is one example of a control circuit. A control circuit can include a processor, PGA (Programmable Gate Array, FPGA (Field Programmable Gate Array), ASIC (Application Specific Integrated Circuit), integrated circuit or other type of circuit.

The (on-chip or off-chip) controller 122 (which in one embodiment is an electrical circuit) may comprise one or more processors 122c, ROM 122a, RAM 122b, a memory interface (MI) 122d and a host interface (HI) 122e, all of which are interconnected. The storage devices (ROM 122a, RAM 122b) store code (software) such as a set of instructions (including firmware), and one or more processors 122c is/are operable to execute the set of instructions to provide the functionality described herein. Alternatively, or additionally, one or more processors 122c can access code from a storage device in the memory structure, such as a reserved area of memory cells connected to one or more word lines. RAM 122b can be to store data for controller 122, including caching program data (discussed below). Memory interface 122d, in communication with ROM 122a, RAM 122b and processor 122c, is an electrical circuit that provides an electrical interface between controller 122 and one or more memory die 108. For example, memory interface 122d can change the format or timing of signals, provide a buffer, isolate from surges, latch I/O, etc. One or more processors 122c can issue commands to control circuit 110 (or another component of memory die 108) via Memory Interface 122d. Host interface 122e provides an electrical interface with host 140 data bus 120 in order to receive commands, addresses and/or data from host 140 to provide data and/or status to host 140.

In one embodiment, memory structure 126 comprises a three-dimensional memory array of non-volatile memory cells in which multiple memory levels are formed above a single substrate, such as a wafer. The memory structure may comprise any type of non-volatile memory that are monolithically formed in one or more physical levels of arrays of memory cells having an active area disposed above a silicon (or other type of) substrate. In one example, the non-volatile memory cells comprise vertical NAND strings with charge-trapping material.

In another embodiment, memory structure 126 comprises a two-dimensional memory array of non-volatile memory cells. In one example, the non-volatile memory cells are NAND flash memory cells utilizing floating gates. Other types of memory cells (e.g., NOR-type flash memory) can also be used. The exact type of memory array architecture or memory cell included in memory structure 126 is not limited to the examples above.

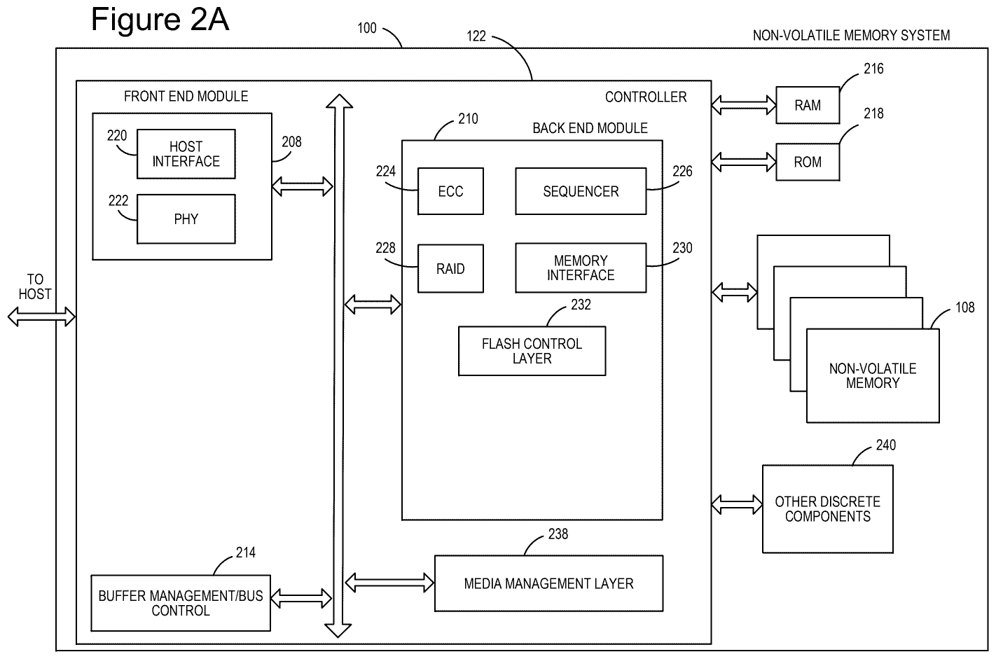

FIG. 2A is a block diagram of example memory system 100, depicting more details of one embodiment of controller 122. The controller in FIG. 2A is a flash memory controller but note that the non-volatile memory die 108 is not limited to flash. Thus, the controller 122 is not limited to the example of a flash memory controller. As used herein, a flash memory controller is a device that manages data stored on flash memory and communicates with a host, such as a computer or electronic device. A flash memory controller can have various functionality in addition to the specific functionality described herein. For example, the flash memory controller can format the flash memory to ensure the memory is operating properly, map out bad flash memory cells, and allocate spare memory cells to be substituted for future failed cells. Some part of the spare cells can be used to hold firmware to operate the flash memory controller and implement other features. In operation, when a host needs to read data from or write data to the flash memory, it will communicate with the flash memory controller. If the host provides a logical address to which data is to be read/written, the flash memory controller can convert the logical address received from the host to a physical address in the flash memory. (Alternatively, the host can provide the physical address). The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between controller 122 and non-volatile memory die 108 may be any suitable flash interface, such as Toggle Mode 200, 400, or 800. In one embodiment, memory system 100 may be a card-based system, such as a secure digital (SD) or a micro secure digital (micro-SD) card. In an alternate embodiment, memory system 100 may be part of an embedded memory system. For example, the flash memory may be embedded within the host. In other example, memory system 100 can be in the form of a solid state drive (SSD).

In some embodiments, memory system 100 includes a single channel between controller 122 and non-volatile memory die 108, the subject matter described herein is not limited to having a single memory channel. For example, in some memory system architectures, 2, 4, 8 or more channels may exist between the controller and the memory die, depending on controller capabilities. In any of the embodiments described herein, more than a single channel may exist between the controller and the memory die, even if a single channel is shown in the drawings.

As depicted in FIG. 2A, controller 122 includes a front end module 208 that interfaces with a host, a back end module 210 that interfaces with the one or more non-volatile memory die 108, and various other modules that perform functions which will now be described in detail.

The components of controller 122 depicted in FIG. 2A may take the form of a packaged functional hardware unit (e.g., an electrical circuit) designed for use with other components, a portion of a program code (e.g., software or firmware) executable by a (micro) processor or processing circuits that usually performs a particular function of related functions, or a self-contained hardware or software component that interfaces with a larger system, for example. For example, each module may include an application specific integrated circuit (ASIC), a Field Programmable Gate Array (FPGA), a circuit, a digital logic circuit, an analog circuit, a combination of discrete circuits, gates, or any other type of hardware or combination thereof. Alternatively, or in addition, each module may include software stored in a processor readable device (e.g., memory) to program a processor for controller 122 to perform the functions described herein. The architecture depicted in FIG. 2A is one example implementation that may (or may not) use the components of controller 122 depicted in FIG. 1 (i.e., RAM, ROM, processor, interface).

Referring again to modules of the controller 122, a buffer manager/bus control 214 manages buffers in random access memory (RAM) 216 and controls the internal bus arbitration of controller 122. A read only memory (ROM) 218 stores system boot code. Although illustrated in FIG. 2A as located separately from the controller 122, in other embodiments one or both of the RAM 216 and ROM 218 may be located within the controller. In yet other embodiments, portions of RAM and ROM may be located both within the controller 122 and outside the controller. Further, in some implementations, the controller 122, RAM 216, and ROM 218 may be located on separate semiconductor die.

Front end module 208 includes a host interface 220 and a physical layer interface (PHY) 222 that provide the electrical interface with the host or next level storage controller. The choice of the type of host interface 220 can depend on the type of memory being used. Examples of host interfaces 220 include, but are not limited to, SATA, SATA Express, SAS, Fibre Channel, USB, PCIe, and NVMe. The host interface 220 typically facilitates transfer for data, control signals, and timing signals.

Back end module 210 includes an error correction code (ECC) engine 224 that encodes the data bytes received from the host and decodes and error corrects the data bytes read from the non-volatile memory. A command sequencer 226 generates command sequences, such as program and erase command sequences, to be transmitted to non-volatile memory die 108. A RAID (Redundant Array of Independent Dies) module 228 manages generation of RAID parity and recovery of failed data. The RAID parity may be used as an additional level of integrity protection for the data being written into the memory system 100. In some cases, the RAID module 228 may be a part of the ECC engine 224. Note that the RAID parity may be added as an extra die or dies as implied by the common name, but it may also be added within the existing die, e.g., as an extra plane, or extra block, or extra WLs within a block. A memory interface 230 provides the command sequences to non-volatile memory die 108 and receives status information from non-volatile memory die 108. In one embodiment, memory interface 230 may be a double data rate (DDR) interface, such as a Toggle Mode 200, 400, or 800 interface. A flash control layer 232 controls the overall operation of back end module 210.

Additional components of memory system 100 illustrated in FIG. 2A include media management layer 238, which performs wear leveling of memory cells of non-volatile memory die 108. Memory system 100 also includes other discrete components 240, such as external electrical interfaces, external RAM, resistors, capacitors, or other components that may interface with controller 122. In alternative embodiments, one or more of the physical layer interface 222, RAID module 228, media management layer 238 and buffer management/bus controller 214 are optional components that are not necessary in the controller 122.

The Flash Translation Layer (FTL) or Media Management Layer (MML) 238 may be integrated as part of the flash management that may handle flash errors and interfacing with the host. In particular, MML may be a module in flash management and may be responsible for the internals of NAND management. In particular, the MML 238 may include an algorithm in the memory device firmware which translates writes from the host into writes to the memory structure 126 of memory die 108. The MML 238 may be needed because: 1) the memory may have limited endurance; 2) the memory structure 126 may only be written in multiples of pages; and/or 3) the memory structure 126 may not be written unless it is erased as a block (or a tier within a block in some embodiments). The MML 238 understands these potential limitations of the memory structure 126 which may not be visible to the host. Accordingly, the MML 238 attempts to translate the writes from host into writes into the memory structure 126.

Controller 122 may interface with one or more memory dies 108. In one embodiment, controller 122 and multiple memory dies (together comprising memory system 100) implement a solid state drive (SSD), which can emulate, replace or be used instead of a hard disk drive inside a host, as a NAS device, in a laptop, in a tablet, in a server, etc. Additionally, the SSD need not be made to work as a hard drive.

Some embodiments of a non-volatile storage system will include one memory die 108 connected to one controller 122. However, other embodiments may include multiple memory die 108 in communication with one or more controllers 122. In one example, the multiple memory die can be grouped into a set of memory packages. Each memory package includes one or more memory die in communication with controller 122. In one embodiment, a memory package includes a printed circuit board (or similar structure) with one or more memory die mounted thereon. In some embodiments, a memory package can include molding material to encase the memory dies of the memory package. In some embodiments, controller 122 is physically separate from any of the memory packages.

In one embodiment, the control circuit(s) (e.g., control circuits 110) are formed on a first die, referred to as a control die, and the memory array (e.g., memory structure 126) is formed on a second die, referred to as a memory die. For example, some or all control circuits (e.g., control circuit 110, row decoder 124, column decoder 132, and read/write circuits 128) associated with a memory may be formed on the same control die. A control die may be bonded to one or more corresponding memory die to form an integrated memory assembly. The control die and the memory die may have bond pads arranged for electrical connection to each other. Bond pads of the control die and the memory die may be aligned and bonded together by any of a variety of bonding techniques, depending in part on bond pad size and bond pad spacing (i.e., bond pad pitch). In some embodiments, the bond pads are bonded directly to each other, without solder or other added material, in a so-called Cu-to-Cu bonding process. In some examples, dies are bonded in a one-to-one arrangement (e.g., one control die to one memory die). In some examples, there may be more than one control die and/or more than one memory die in an integrated memory assembly. In some embodiments, an integrated memory assembly includes a stack of multiple control die and/or multiple memory die. In some embodiments, the control die is connected to, or otherwise in communication with, a memory controller. For example, a memory controller may receive data to be programmed into a memory array. The memory controller will forward that data to the control die so that the control die can program that data into the memory array on the memory die.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 307. One or more integrated memory assemblies 307 may be used in a memory package in memory system 100. The integrated memory assembly 307 includes two types of semiconductor die (or more succinctly, “die”). Memory die 301 includes memory structure 126.

Control die 311 includes column control circuits 364, row control circuits 320 and system control logic 360 (including state machine 312, power control module 316 (including charge pumps 117), storage 366, and memory interface 368). In some embodiments, control die 311 is configured to connect to the memory array 126 in the memory die 301. FIG. 2B shows an example of the peripheral circuits, including control circuits, formed in a peripheral circuit or control die 311 coupled to memory array 126 formed in memory die 301. System control logic 360, row control circuits 320, and column control circuits 364 are located in control die 311. In some embodiments, all or a portion of the column control circuits 364 and all or a portion of the row control circuits 320 are located on the memory die 301. In some embodiments, some of the circuits in the system control logic 360 is located on the on the memory die 301.

System control logic 360, row control circuits 320, and column control circuits 364 may be formed by a common process (e.g., CMOS process), so that adding elements and functionalities, such as ECC, more typically found on a memory controller 102 may require few or no additional process steps (i.e., the same process steps used to fabricate memory controller 102 may also be used to fabricate system control logic 360, row control circuits 320, and column control circuits 364). Thus, while moving such circuits from a die such as memory die 301 may reduce the number of steps needed to fabricate such a die, adding such circuits to a die such as control die 311 may not require many additional process steps.

FIG. 2B shows column control circuits 364 including sense block(s) 350 on the control die 311 coupled to memory array 126 on the memory die 301 through electrical paths 370. For example, electrical paths 370 may provide electrical connection between column decoder 332, driver circuits 372 (bit line driver circuits), and block select 373 and bit lines of memory array (or memory structure) 126. Electrical paths may extend from column control circuits 364 in control die 311 through pads on control die 311 that are bonded to corresponding pads of the memory die 301, which are connected to bit lines of memory structure 126. Each bit line of memory structure 126 may have a corresponding electrical path in electrical paths 370, including a pair of bond pads, which connects to column control circuits 364. Similarly, row control circuits 320, including row decoder 324, array drivers 374 (word line driver circuits), and block select 376 are coupled to memory array 126 through electrical paths 308. Each of electrical path 308 may correspond to a word line, dummy word line, or select gate line. Additional electrical paths may also be provided between control die 311 and memory die 301.

In some embodiments, there is more than one control die 311 and/or more than one memory die 301 in an integrated memory assembly 307. In some embodiments, the integrated memory assembly 307 includes a stack of multiple control die 311 and multiple memory dies 301. In some embodiments, each control die 311 is affixed (e.g., bonded) to at least one of the memory dies 301.

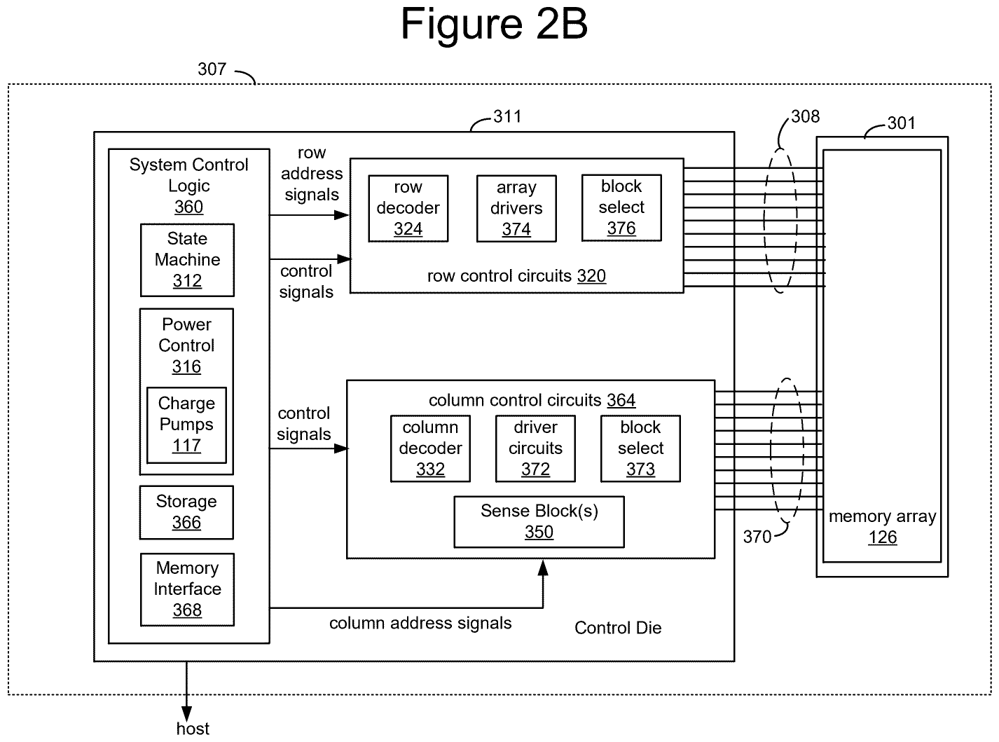

FIG. 3 is a perspective view of a portion of one example embodiment of a monolithic three dimensional memory array that can comprise memory structure 126, which includes a plurality non-volatile memory cells. For example, FIG. 3 shows a portion of one block of memory. The structure depicted includes a set of bit lines BL positioned above a stack of alternating layers of dielectric material and conductive material on a substrate. For example, one of the dielectric layers is marked as D and one of the conductive layers (also called word line layers) is marked as W. The number of alternating dielectric layers and conductive layers can vary based on specific implementation requirements. One set of embodiments includes between 108-300 alternating dielectric layers and conductive layers. One example embodiment includes 96 data word line layers, 8 select layers, 6 dummy word line layers and 110 dielectric layers. More or less than 108-300 layers can also be used. Data word line layers have data memory cells. Dummy word line layers have dummy memory cells. As will be explained below, the alternating dielectric layers and conductive layers are divided into “fingers” in regions that are separated by local interconnects LI. FIG. 3 shows two regions, each with respective NAND strings, and two local interconnects LI. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data.

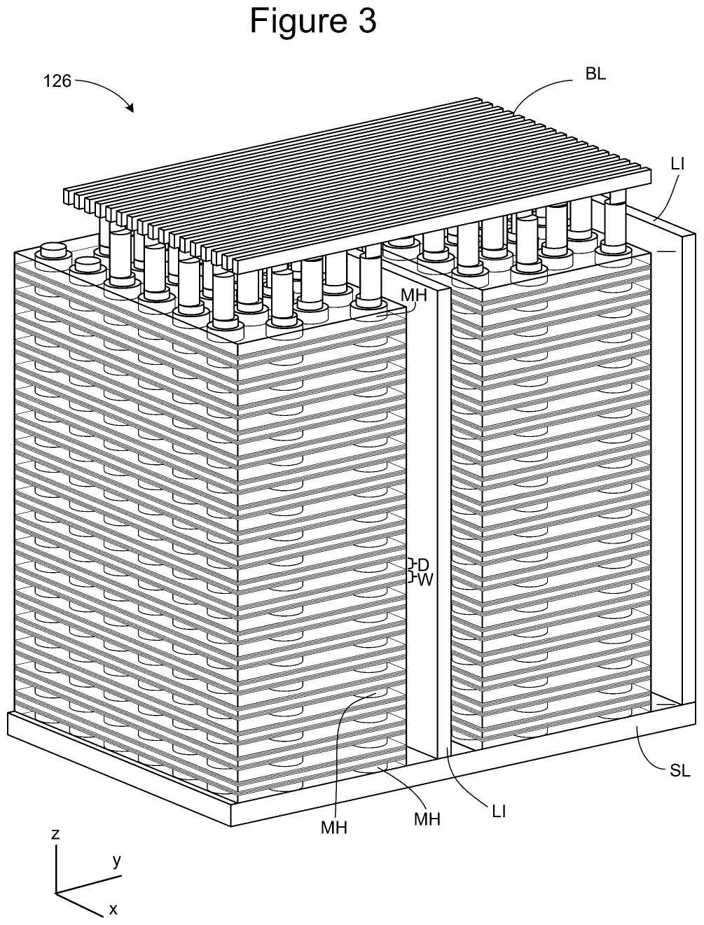

FIG. 4A is a block diagram explaining one example organization of memory structure 126, which is divided into two planes 302 and 304. Each plane is then divided into M blocks. In one example, each plane has about 2000 blocks. However, different numbers of blocks and planes can also be used. In one embodiment, for two plane memory, the block IDs are usually such that even blocks belong to one plane and odd blocks belong to another plane; therefore, plane 302 includes block 0, 2, 4, 6, . . . and plane 304 includes blocks 1, 3, 5, 7, . . . . In on embodiment, a block of memory cells is a unit of erase. That is, all memory cells of a block are erased together. In other embodiments, memory cells can be grouped into blocks for other reasons, such as to organize the memory structure 126 to enable the signaling and selection circuits.

FIGS. 4B-4C depict an example 3D NAND structure. FIG. 4B is a block diagram depicting a top view of a portion of one block from memory structure 126. The portion of the block depicted in FIG. 4B corresponds to portion 306 in block 2 of FIG. 4A. As can be seen from FIG. 4B, the block depicted in FIG. 4B extends in the direction of 332. In one embodiment, the memory array will have 60 layers. Other embodiments have less than or more than 60 layers (e.g., However, FIG. 4B only shows the top layer.

FIG. 4B depicts a plurality of circles that represent the vertical columns. Each of the vertical columns include multiple select transistors and multiple memory cells. In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. The block may include more vertical columns than depicted in FIG. 4B

FIG. 4B also depicts a set of bit lines 425, including bit lines 411, 412, 413, 414, . . . 419. FIG. 4B shows twenty-four bit lines because only a portion of the block is depicted. It is contemplated that more than twenty-four bit lines connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together at the end of the block to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side select lines and the drain side select lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts a portion of an embodiment of three-dimensional memory structure 126 showing a cross-sectional view along line AA of FIG. 4B. This cross-sectional view cuts through vertical columns 432 and 434 and region 430 (see FIG. 4B). The structure of FIG. 4C includes four drain side select layers SGD0, SGD1, SGD2 and SGD3; four source side select layers SGS0, SGS1, SGS2 and SGS3; four dummy word line layers DD0, DD1, DS0 and DS1; and forty-eight data word line layers WLL0-WLL47 for connecting to data memory cells. Other embodiments can implement more or less than four drain side select layers, more or less than four source side select layers, more or less than four dummy word line layers, and more or less than forty-eight-word line layers (e.g., 96 word line layers or more than 100 word line layers). Vertical columns 432 and 434 are depicted protruding through the drain side select layers, source side select layers, dummy word line layers and word line layers. In one embodiment, each vertical column comprises a NAND string. For example, vertical column 432 comprises NAND string 484. Below the vertical columns and the layers listed below is substrate 101, an insulating film 454 on the substrate, and source line SL. The NAND string of vertical column 432 has a source end at a bottom of the stack and a drain end at a top of the stack. As in agreement with FIG. 4B, FIG. 4C show vertical column 432 connected to bit line 414 via connector 415. Local interconnects 404 and 406 are also depicted.

Bit line 414 is connected to pad 416 by via 417. Additional bit lines that are coupled to additional vertical columns are similarly connected. A number of bit lines may extend over such a memory structure and may connect to multiple blocks through block select circuits. Such bit lines are connected to pads that may be exposed along a top surface (primary surface) of a work piece so that they can be used to form electrical connection. Similarly, word lines (e.g. WLL0-WLL47), dummy word lines (e.g. DD0-1, DS0-1), and select lines (e.g. SGD0-SGD3) may be coupled by vias (not shown in FIG. 4C) to pads on the primary surface of a workpiece (e.g. pads that are co-planar with pad 416). For example, word line layers may be arranged in a stepped “staircase” arrangement in an outer area (outside area where memory cells are formed) so that each word line layer is exposed and can be contacted by a via.

The non-volatile memory cells are formed along vertical columns which extend through alternating conductive and dielectric layers in the stack. In one embodiment, the memory cells are arranged in NAND strings. The word line layer WLL0-WLL47 connect to memory cells (also called data memory cells). Dummy word line layers DD0, DD1, DS0 and DS1 connect to dummy memory cells. A dummy memory cell does not store user data, while a data memory cell is eligible to store user data. Drain side select layers SGD0, SGD1, SGD2 and SGD3 are used to electrically connect and disconnect NAND strings from bit lines. Source side select layers SGS0, SGS1, SGS2 and SGS3 are used to electrically connect and disconnect NAND strings from the source line SL.

The exact type of memory array architecture or memory cell included in memory structure 126 is not limited to the examples above. Many different types of memory array architectures or memory cell technologies can be used to form memory structure 126. No particular non-volatile memory technology is required for purposes of the new claimed embodiments proposed herein. Other examples of suitable technologies for memory cells of the memory structure 126 include ReRAM memories, magnetoresistive memory (e.g., MRAM, Spin Transfer Torque MRAM, Spin Orbit Torque MRAM), phase change memory (e.g., PCM), and the like. Examples of suitable technologies for architectures of memory structure 126 include two dimensional arrays, three dimensional arrays, cross-point arrays, stacked two dimensional arrays, vertical bit line arrays, and the like. A person of ordinary skill in the art will recognize that the technology described herein is not limited to a single specific memory structure, but covers many relevant memory structures within the spirit and scope of the technology as described herein and as understood by one of ordinary skill in the art.

One example of a ReRAM memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. This configuration is known as a spin valve and is the simplest structure for an MRAM bit. A memory device is built from a grid of such memory cells. In one embodiment for programming a non-volatile storage system, each memory cell lies between a pair of write lines arranged at right angles to each other, parallel to the cell, one above and one below the cell. When current is passed through them, an induced magnetic field is created.

Phase change memory (PCRAM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse, but includes a (continuous or non-continuous) vibration or burst of sound, current, voltage light, or other wave.

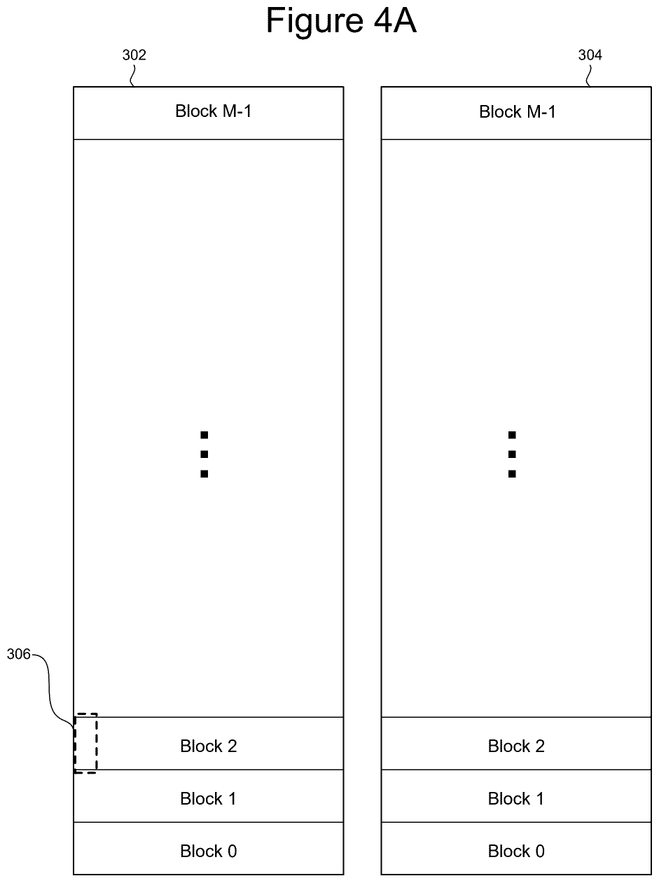

FIG. 5A illustrates the process of wafer-to-wafer bonding of wafer 500 and wafer 600. Substrate 501 is processed to fabricate memory dies that include nonvolatile memory arrays (e.g. memory structure 126), interconnect structures, and pads for bonding as discussed above with respect to FIGS. 3 and 4A-C, thereby forming wafer 500. Substrate 601 is processed to fabricate control dies that include memory control circuits (e.g. logic circuits formed as CMOS circuits), interconnect structures, and pads for bonding as discussed above with respect to FIG. 2B, thereby forming wafer 600. Wafer 500 is then flipped over in this example (either wafer may be flipped) so that primary surface 506 of wafer 500 opposes primary surface 606 of wafer 600. Wafers 500 and 600 are aligned so that corresponding dies are aligned in pairs (in a one-to-one arrangement of memory dies and control dies) and pads on such pairs of dies are aligned for bonding. Subsequently, with wafers 500, 600 aligned, pressure and/or heat or other conditions are applied to wafers 500, 600 to bond respective pads together and thus form electrical connections between memory arrays of wafer 500 and control circuits of wafer 600 (i.e. bonded along an interface between primary surfaces 506, 606). Bonded wafers 500 and 600 form a combined wafer 700 that includes pairs of dies, with each pair including a memory die and a control die that form a memory system. Combined wafer 700 may be scribed (diced) into pairs of dies 702 for packaging. Combined wafer 700 or a portion of such a wafer may be referred to as a CMOS bonded Array (CbA) and an individual pair of dies 702 (memory die and control die) may be referred to as an integrated memory assembly.

One feature of wafer-to-wafer bonding as described with respect to FIG. 5 is die-size matching (e.g., the one-to-one relationship between memory dies and control dies may require both dies to have identical dimensions). In some cases, such a one-to-one correspondence may not be optimal. For example, as the number of word line layers in 3D memory structures and the number of bits per memory cell increase, memory density increases, which may allow a reduction in memory die size. Reduction in control die size (e.g., due to reduced minimum feature size) may not match reduction in memory die size. In order to maintain equal sizing of memory and control die for die-size matching, memory die size may be larger than necessary, which may be costly (e.g., memory wafers may be more expensive to manufacture than control circuit wafers so that wasted space on a memory die may be expensive) and may obviate the advantages that may be obtained from high density memory structures.

Another feature of the one-to-one relationship between memory dies and control dies of FIG. 5 is that the failure rate for integrated memory assemblies may be relatively high and a number of “good” dies (memory dies and control dies that meet a specification and are not defective) may be wasted. Good memory dies may be bonded to bad control dies and good control dies may be bonded to bad memory dies resulting in bad integrated memory assemblies. For example, where 5% of memory dies are bad (defective) and 5% of control dies are bad (defective) the resulting yield loss may be about 10% (e.g., about 10% of resulting integrated memory assemblies are defective because of either a defective memory die or a defective control die). Even if bad dies are identified prior to bonding, wafer-to-wafer bonding may not allow any rearrangement of die pairing (e.g., a given die is paired with a corresponding die based on its physical location in a wafer, which may not be changeable prior to wafer-to-wafer bonding).

According to aspects of the present technology, integrated memory assemblies may be formed in a manner that is not limited to the one-to-one arrangement of FIG. 5, is not constrained by die-size matching and may allow integration of high-density memory structures in an efficient manner with lower failure rates than wafer-to-wafer bonding (e.g., fewer defective integrated memory assemblies for given die failure rates). According to examples presented below, two or more memory dielets or chiplets (e.g., memory dies such as memory die 301 having a memory array structure 126 that may form one or more plane or sub-plane and that is not limited by die-size matching) may be combined with (e.g., directly bonded to) a control die that has slots (e.g., bond pad arrangements connected to corresponding control circuits) to accommodate multiple memory chiplets. Each memory chiplet may consist of an appropriate unit of a memory structure (e.g., one, two or more planes or sub-planes of NAND memory). Memory chiplets in such an arrangement may be identical or different. For example, chiplets may have different capacities (e.g., number of planes or blocks), different structures (e.g., different numbers of layers), different configurations (e.g., configured to store different numbers of bits per cell) and/or otherwise be non-identical. Such an arrangement may be adaptable to different needs (e.g., capacity is configurable by using chiplets of different capacities and/or different numbers of chiplets) and may combine high-performance and low-cost (e.g., some high-performance chiplets for demanding applications and some low-cost chiplets for less demanding applications). Testing of chiplets and/or control dies prior to assembly may reduce the number of defective integrated memory assemblies (e.g., compared with wafer-to-wafer bonding). For example, defective control dies in a wafer may be identified, marked as defective and may not be bonded to any chiplets while defective chiplets may be identified and discarded without being bonded to any control dies. Such die screening prior to bonding may have significant benefits. For example, where 5% of memory chiplets and 5% of control dies are defective, the defective memory chiplets are discarded and the remaining good memory chiplets (95%) are bonded to good control dies (no bonding to the 5% of control dies that are defective) so that the yield loss is limited to 5% (e.g., about half of the yield loss wafer-to-wafer bonding of similar dies).

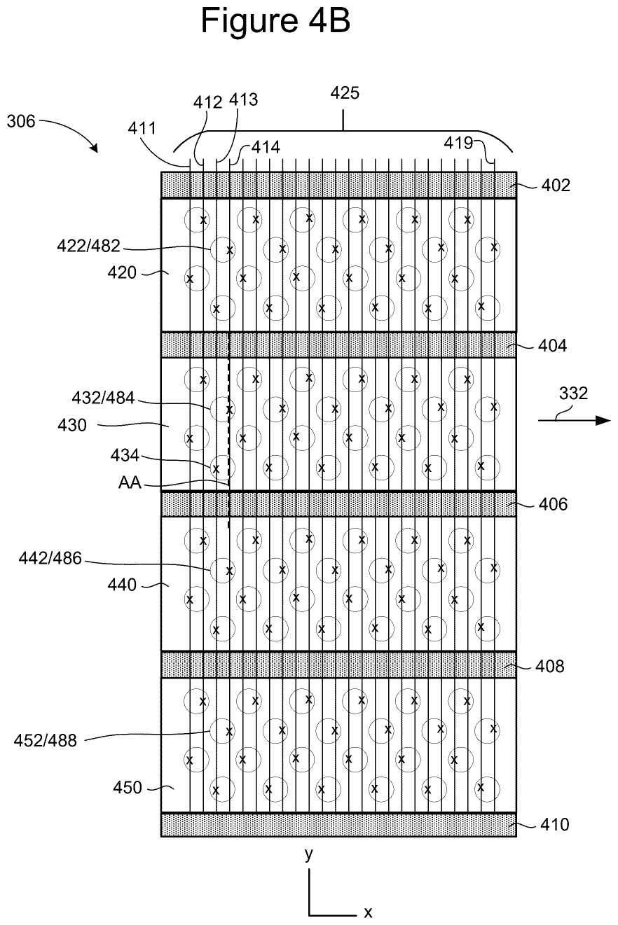

FIGS. 6A-B show an example of die-to-wafer bonding in which four memory chiplets (memory dies) 610a-d are bonded to a control die 612 in a silicon wafer 600. For example, silicon wafer 600 may include a large number of control dies including control dies 612 and 614 shown in FIG. 6A. In some cases, one or more defective control dies may be detected prior to assembly of integrated memory assemblies (e.g., prior to bonding memory chiplets to control dies as shown in FIG. 6A). In the example shown, control die 614 is detected as a defective control die and consequently no memory chiplets are bonded to control die 614. Unlike the wafer-to-wafer bonding example of FIG. 5, bonding may be selective on a die-by-die basis so that defective dies may be omitted from bonding thereby saving resources.

FIG. 6B shows a top-down view of control die 612 showing upper (first) surface 616, which includes four slots 616a-d corresponding to the four memory chiplets 610a-d. Each slot 616a-d may include bond pads for bonding to corresponding bond pads of memory chiplets 610a-d and each slot may have dimensions to accommodate a memory chiplet (e.g., dimensions equal to or greater than those of an opposing (second) surface of a memory chiplet or die).

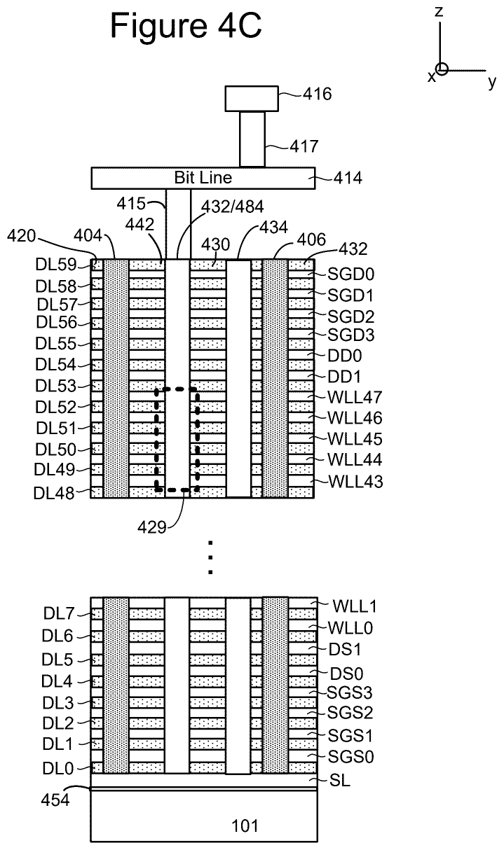

FIGS. 7A-B show another example of die-to-wafer bonding in which eight memory chiplets (memory dies) 620a-h are bonded to a control die 622 in a silicon wafer 600. For example, silicon wafer 600 may include a large number of control dies including control dies 622 and 624 shown in FIG. 7A. Defective control dies may be detected prior to assembly of integrated memory assemblies (e.g., prior to bonding memory chiplets to control dies as shown in FIG. 7A). In the example shown, control die 624 is detected as a defective control die and consequently no memory chiplets are bonded to control die 624.

FIG. 7B shows a top-down view of control die 622 showing upper (first) surface 626, which includes eight slots 626a-h corresponding to the eight memory dies 620a-h. Each slot 626a-h may include bond pads for bonding to corresponding bond pads of memory dies 620a-h and each slot may have dimensions to accommodate a memory die (e.g., dimensions equal to or greater than those of an opposing (second) surface of a memory chiplet or die).

While the examples of FIGS. 6A-7B show four and eight slots respectively, the number of slots and the arrangement of slots are not limited to any particular number or arrangement. The examples described here are for purposes of illustration and are not intended to provide an exhaustive list of all possible implementations. Furthermore, the control dies in a given silicon wafer may not be identical. For example, a single silicon wafer may include control dies having four slots (e.g., control die 612) and control dies having eight slots (e.g., control die 622) or dies that are otherwise different.

In addition to providing flexibility as to whether to bond dies (e.g., only bonding good dies), aspect of the present technology may provide flexibility as to how many memory chiplets and what type(s) of memory chiplets to bond to a given control die. It is not generally required that every slot on a control die be occupied by a memory chiplet in order to form a functional integrated memory assembly.

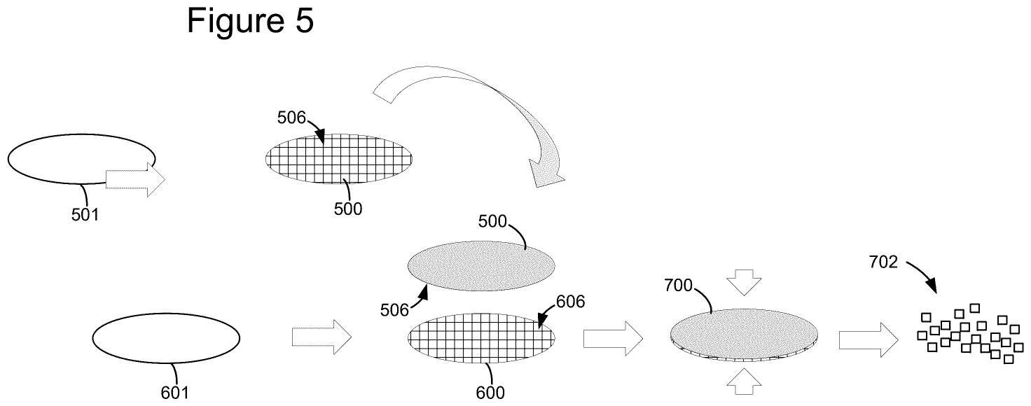

For example, FIGS. 8A-B show the case where control die 612 has four slots 616a-d with two used (occupied) slots, 616a and 616c, and two unused (empty) slots, 616b and 616d. Memory chiplets 610a and 610c are bonded in corresponding slots 616a and 616c, while no memory chiplets are bonded in slots 616b and 616d, which remain empty. The assembly consisting of control die 612 and memory chiplets 610a and 610c may be considered a completed integrated memory assembly.

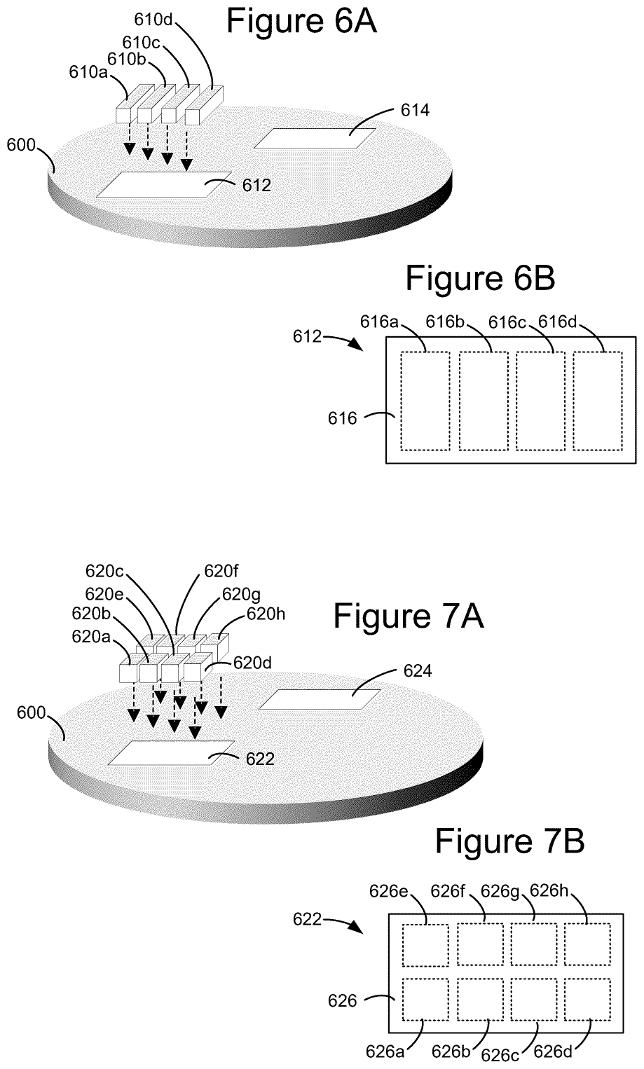

FIGS. 9A-B show another example in which control die 622 has eight slots 626a-h, with six slots, 626a and 626c-g, used and two slots, 626b and 626h, unused. Memory chiplets 620a and 620c-g are bonded in corresponding slots 626a and 626c-g, while no memory chiplets are bonded in slots 626b and 626h, which remain empty. The assembly consisting of control die 622 and memory chiplets 620a and 620c-g may be considered a completed integrated memory assembly.

According to aspects of the present technology, an integrated memory assembly may be formed using different memory chiplets (e.g., memory chiplets having different structures, capacities, configurations and/or that are otherwise different).

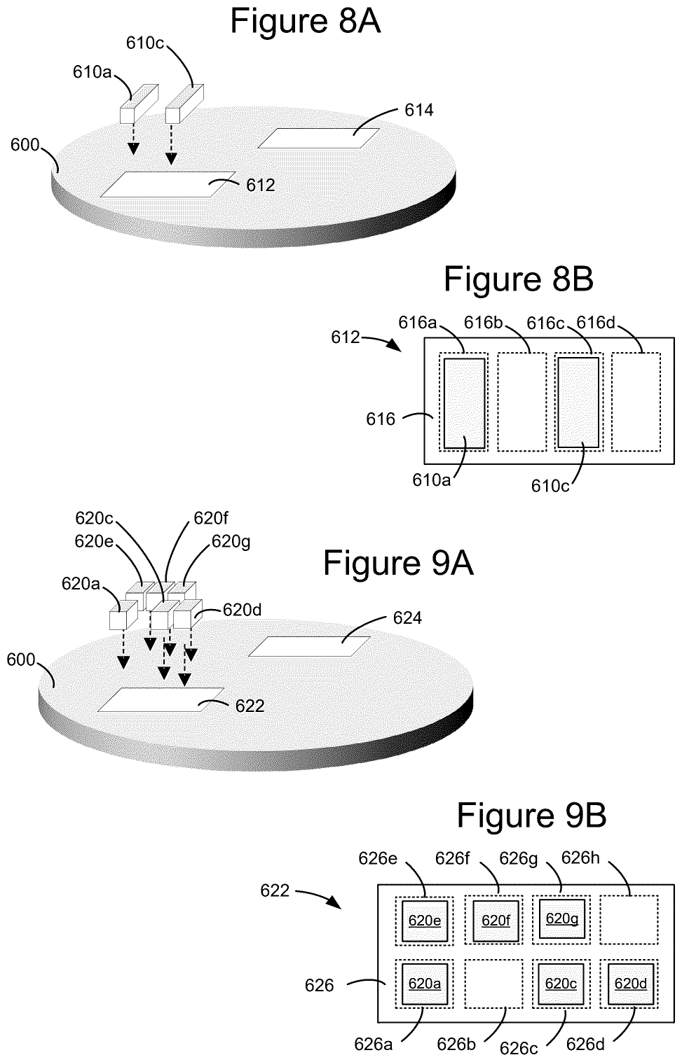

FIGS. 10A-B show an example in which non-identical memory chiplets are bonded to control die 622 to form an integrated memory assembly. Memory chiplets 630a and 630c-g are not identical. For example, memory chiplet 630a is physically larger than memory chiplets 630c-g and occupies two slots, 626a and 626e. Memory chiplet 630a may be designed to interface with bond pads of two slots so that it can be bonded in as shown (e.g., a slot may define a minimum memory chiplet footprint and bond pad arrangement without limiting chiplet size to a single slot). Memory chiplet 630c is smaller than memory chiplet 630a (e.g., approximately half the size) and may have a smaller capacity accordingly (e.g., half the capacity where structure and configuration are similar). Memory chiplet 630d has a greater number of layers than memory chiplet 630c (e.g., more word line layers and more memory cells, which provide more data storage capacity). Memory chiplet 630f has a different configuration to memory chiplet 630c (for example, whereas memory chiplet 630c may be configured to store four bits per cell (QLC), memory chiplet 630f may be configured to store three bits per cell (TLC) or one bit per cell (SLC)). Memory chiplet 630g may have a different structure to memory chiplet 630c. For example, while memory chiplet 630c may have a 3D NAND flash memory structure, memory chiplet 630g may have a different structure (e.g., ReRAM, MRAM, PCM or other structure). While the different memory chiplets shown in FIGS. 10A-B are provided as examples, the range of memory chiplets that may be bonded to a single control die is not limited to the examples described.

Forming an integrated memory assembly from memory chiplets that have different characteristics allows customization of integrated memory assemblies for particular uses in a cost-effective manner (e.g., combining high-performance memory chiplets with cheaper, low-performance memory chiplets). Memory chiplets manufactured using older technology may be integrated with memory chiplets using newer technology to obtain the benefits of newer technology at a lower total cost. The data storage capacities of such integrated memory assemblies may be configured by selecting the number and capacities of memory chiplets used. A common control die may be used to provide integrated memory assemblies with a range of different capacities. Integrated memory assemblies with different capacities (and/or other different characteristics) may be formed in the same manufacturing facility and may be formed from the same silicon wafer (e.g., silicon wafer 600 may include control dies that are bonded to a different set of memory chiplets than those bonded to control die 622).

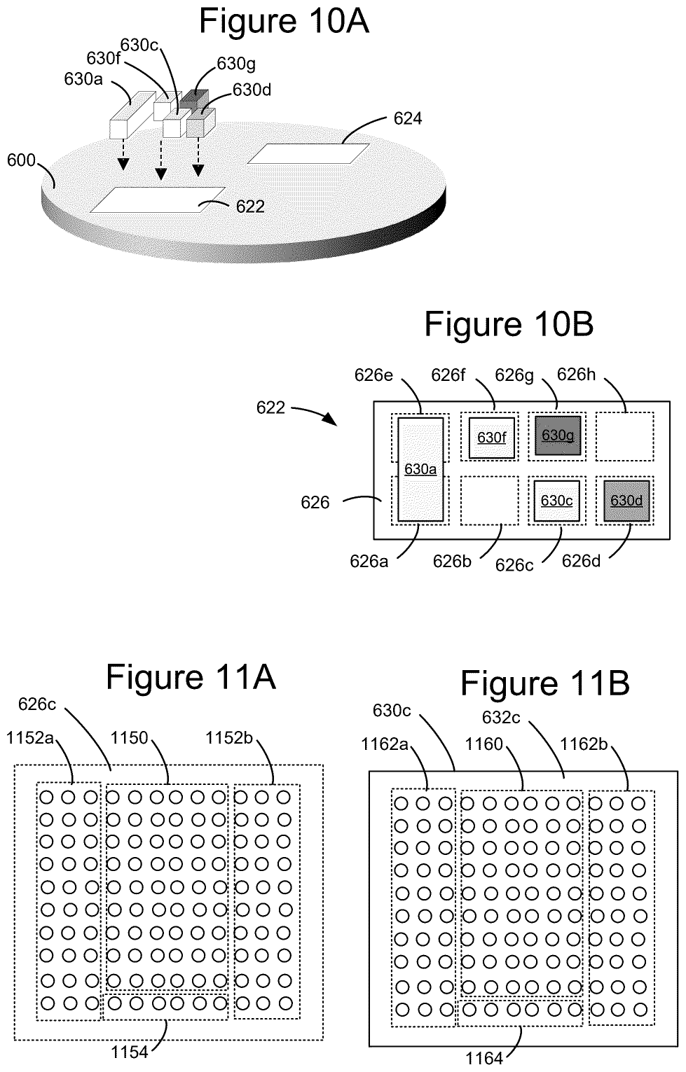

Bond pads of a slot (e.g., any off slots 626a-h on surface 626 of FIG. 10B) may be arranged to align with correspond bond pads on a (second) surface of a memory chiplet. FIG. 11A shows an example of bond pads of slot 626c, which includes bit line bond pads 1150 located in the middle of slot 626c and word line bond pads 1152a, 1152b located on either side of bit line bond pads 1150. Bit line bond pads 1150 may be connected to bit line driver circuits (e.g., driver circuits 372 of column control circuits 364) in control die 622. Worldline bond pads 1152a-b may be connected to word line driver circuits (e.g., array drivers 374 of row control circuits 320) in control die 622. Additional bond pads 1154 are provided in slot 626c and may include pads providing one or more voltages, for example ground or 0 volts; supply voltage(s) such as 3 volts, 5 volts or other nonzero voltage, one or more clock signal and/or voltages or signals that may be used by a memory chiplet.

FIG. 11B shows corresponding bond pads on a surface 632c (second surface) of memory chiplet 630c that correspond to (and, in FIG. 10B are bonded to) bond pads of slot 626c shown in FIG. 11A. FIG. 11B shows bit line bond pads 1160 located in the middle of surface 632c and word line bond pads 1162a, 1156b located on either side of bit line bond pads 1160. Bit line bond pads 1160 may be connected to bit lines in memory chiplet 630c (e.g., pad 416 connected to bit line 414 in FIG. 4C). Worldline bond pads 1162a-b may be connected to word lines in memory chiplet 630c (e.g., word lines WLL0 to WLL47 of FIG. 4C). Additional bond pads 1164 are provided on surface 632c and may correspond to additional bond pads 1154 (e.g., pads for one or more voltage(s), clock signal(s) and/or other signals).

During manufacturing of an integrated memory assembly, a memory chiplet may be aligned so that bond pads of the memory chiplet align with corresponding bond pads of a slot on a surface of a control die. For example, memory chiplet 630c is aligned with slot 626c so that first bit line bond pads 1150 of slot 626c and second bit line bond pads 1160 on surface 632c are aligned, first word line bond pads 1152a-b and second word line bond pads 1162a-b are aligned and first additional bond pads 1154 and second additional bond pads 1164 are aligned. Bonding of bond pads may then be performed so that first bit line bond pads 1150 are bonded to second bit line bond pads 1160, first word line bond pads 1152a-b are bonded to second word line bond pads 1162a-b and first additional bond pads 1154 are bonded to second additional bond pads 1164, which results in connection of control circuits in control die 622 with corresponding components of memory chiplet 630c (e.g., bit line drivers connected to bit lines and word line drivers connected to word lines).

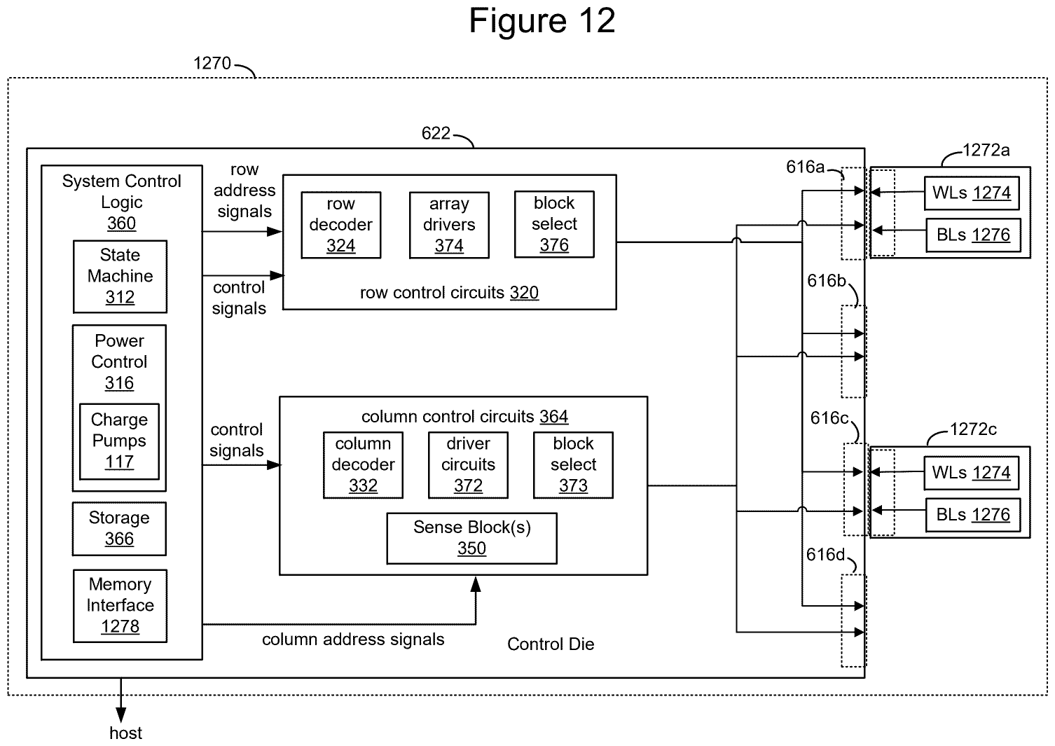

FIG. 12 illustrates an example of an integrated memory assembly 1270 formed by bonding two memory chiplets, 1272a and 1272c, to control die 622. Certain components of control die 622 were previously described with respect to control die 311 of integrated memory assembly 307 (FIG. 2B) and are not further described here.

In contrast to integrated memory assembly 307, integrated memory assembly 1270 includes two memory chiplets, 1272a and 1272c, that are connected to corresponding slots, 616a and 616c, of control die 622. Memory chiplets 1272a and 1272c each include word lines 1274 and bit lines 1276 and are aligned and bonded so that pads of memory chiplets 1272a and 1272c are bonded to corresponding pads of slots 616a and 616c to connect WLs 1274 to row control circuits 320 and connect BLs 1276 to column control circuits 364. Slots 616b and 616d are unused in integrated memory assembly 1270. System control logic 360 may include circuits to detect the presence/absence of memory chiplets at each of slots 616a-d and to configure operation accordingly. For example, memory interface circuit 1278 may be configured to detect presence/absence of memory chiplets at each slot 616a-d (and may perform additional detection, for example, of capacity and/or configuration of each memory chiplet). The physical configuration (number and types of memory chiplets) may be used to determine space available for data storage (e.g., to initiate logical-to-physical mapping). Memory access operations (e.g., write, read and erase operations) may be directed according to the configuration detected by memory interface circuit 1278 (e.g., accessing memory chiplets 1272a and 1272c through corresponding slots 616a and 616c without attempting access through slots 616b and 616d).

In an example of the present technology, a silicon wafer that includes control dies (e.g., silicon wafer 600) and/or a silicon wafer that includes memory chiplets (e.g., a silicon wafer containing any of memory chiplets 610a-d, 620a-h, 630a-g) may be evaluated prior to performing die-to-wafer bonding to determine if they meet desired specifications. In some examples, metrology may be used to visually detect defects and the die or chiplet may be marked as defective if such defects are observed. In some examples, metrology data regarding film thickness, film quality, etch depth, pattern alignment or other metrology may be used to detect defective dies and/or chiplets. In addition, in some cases, electrical testing may be performed to evaluate dies and/or chiplets. For example, probe pads may be located on a surface of a die or chiplet to enable electrical connection of test equipment to components of a die or chiplet. Surface area of a memory chiplet may be limited so that adding such probe pads may be challenging without increasing area, which is costly. Aspects of the present technology provide technical solutions to the technical problems of obtaining test data from memory dies or chiplets in an area-efficient manner (e.g., to enable pre-bonding screening of defective dies).

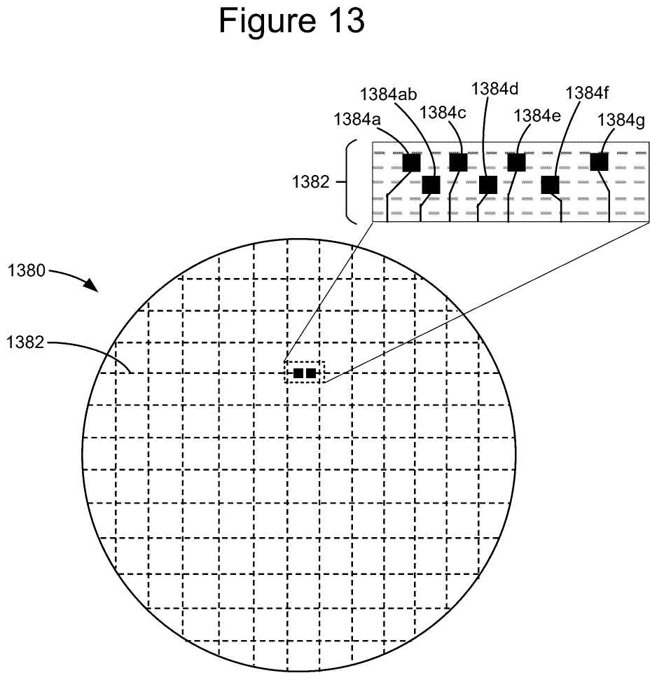

FIG. 13 shows an example of a silicon wafer 1380 that includes memory chiplets (e.g., any of memory chiplets 610a-d, 620a-h, 630a-g). While FIG. 13 shows silicon wafer 1380 as a single physical body, silicon wafers may be divided into individual dies or chiplets by scribing the silicon wafer along scribe lines (shown as dotted lines in FIG. 13) arranged in a grid pattern. An example of a scribe line 1382 is shown in FIG. 13 and a portion of scribe line 1382 is shown in close-up including probe pads 1384a-g. Probe pads 1384a-g (and additional probe pads that are not visible in this view) may be electrically connected to components of memory chiplets of silicon wafer 1380 (e.g., to word lines and/or bit lines), which may allow probing of components prior to scribing of silicon wafer 1380 (e.g., probes that are connected to test equipment may be brought into physical and electrical contact with probe pads 1384a-g). For example, probe pads connected to word lines and bit lines may be probed to identify word line-to-word line short circuits, bit line-to-bit line short circuits, word line-to-bit line short circuits, bit line open defects, bit line leakage and/or other defects.

The area occupied by a scribe line (scribe alley or scribe area) may be removed during the scribing process. For example, a saw or laser may be used to remove a portion of wafer material (e.g., silicon and any structures formed on or in the silicon) between dies to separate dies from each other and from the silicon wafer. In the example of FIG. 13, probe pads 1384a-g, which are formed in the scribe area of scribe line 1382 are removed during scribing so that these components are no longer present during bonding. Locating such components in scribe area not only ensures that die size is not affected by the addition of such structures but also ensures that they are removed prior to bonding, which may be beneficial because the presence of such probe pads after probing is complete could contribute to chiplet surface nonuniformity, which could affect bonding of chiplets to a control die (e.g., probe marks resulting from the probing process may contribute to surface nonuniformity and probing may leave contamination).

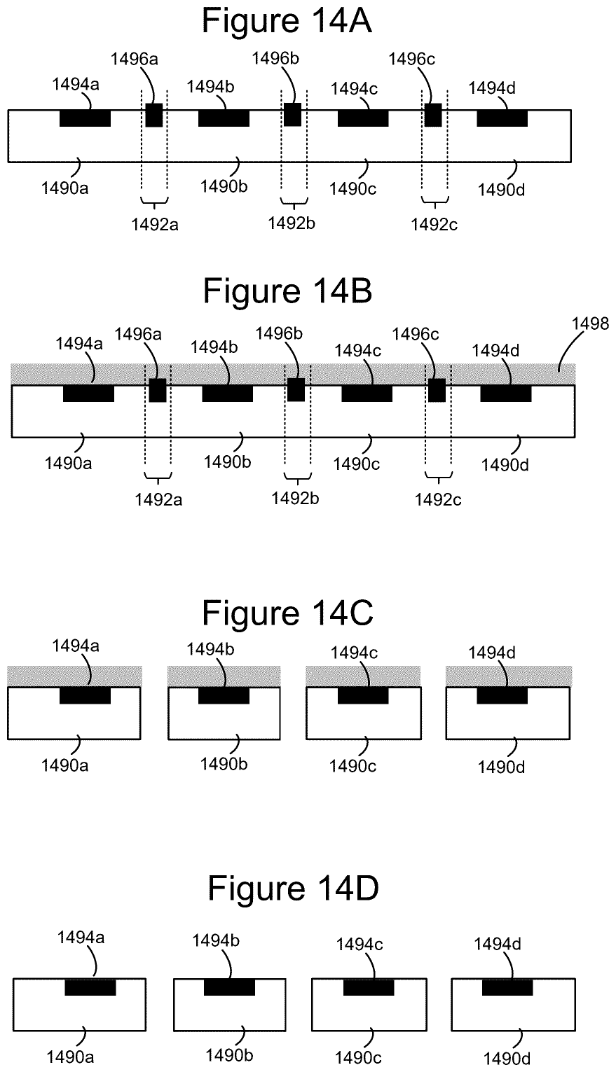

FIGS. 14A-D illustrates removal of scribe areas in an example of a scribing process to separate individual memory chiplets. FIG. 14A shows a portion of a silicon wafer that includes memory chiplets including memory chiplets 1490a-d in cross-section prior to scribing. Memory chiplets 1490a-d are separated by scribe areas 1492a-c. Bond pads 1494a-d are shown in the upper surfaces of respective memory chiplets 1490a-d (a single bond pad is shown in each memory chiplet for simplicity of illustration). FIG. 14A also shows probe pads 1496a-c formed in scribe areas 1492a-c respectively.

FIG. 14B shows the portion of FIG. 14A after deposition of a protective layer 1498 (e.g., a layer of an organic material that may be spun-on, deposited or otherwise applied). Protective layer 1498 covers upper surfaces of memory chiplets 1490a-d during scribing to avoid damage and contamination that may result from scribing (e.g., damage from debris caused by scribing).

FIG. 14C shows memory chiplets 1490a-d after scribing, with all material in scribe areas 1492a-c removed, leaving memory chiplets 1492a-d as physically separate bodies.

FIG. 14D shows memory chiplets 1490a-d after removal of portions of protective layer 1498, leaving bond pads 1494 exposed and ready for bonding (e.g., to corresponding bond pads of a control die).

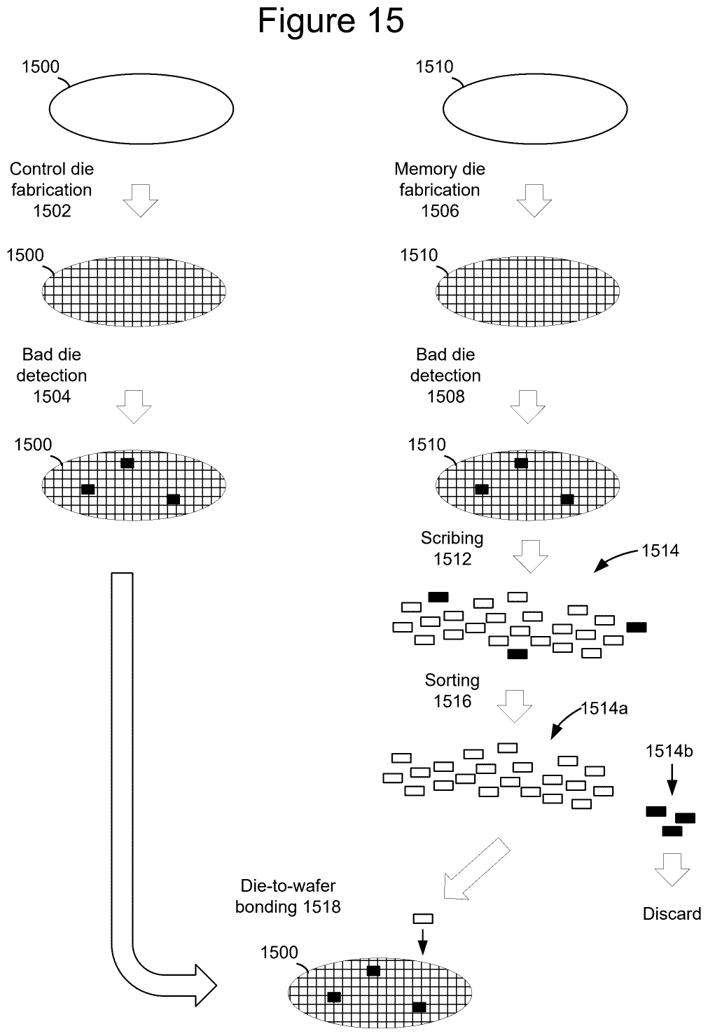

FIG. 15 illustrates an example of a method of manufacturing integrated memory assemblies according to an example of the present technology. A first silicon wafer 1500 (control wafer) is used for control die fabrication 1502 to form control dies in first silicon wafer 1500. Bad die detection 1504 is used to identify bad control dies in first silicon wafer 1500 (e.g., using metrology during or after fabrication and/or testing using external text equipment connected by probes and/or on-chip testing using built in self-test circuits).

FIG. 15 also shows a second silicon wafer 1510 (memory wafer) which is used for memory die fabrication 1506 to form memory dies or chiplets in second silicon wafer 1510. Bad die detection 1508 is used to identify bad memory dies in second silicon wafer 1510. Bad die detection 1508 may include using metrology during or after fabrication and/or testing using external test equipment connected by probes and/or on-chip testing using built in self-test circuits. For example, bad die detection 1508 may include using probe pads located in scribe areas of second silicon wafer 1510 to detect defects (e.g., short circuits). Subsequently, scribing 1512 divides second silicon wafer 1510 into individual memory dies or chiplets 1514. Sorting 1516 then separates good memory dies 1514a and bad memory dies 1514b. Bad memory dies 1514b may be discarded. Memory dies 1514 may additionally be sorted according to various metrics based on testing (e.g., testing is not limited to making a good/bad determination). Good memory dies 1514a are bonded to good control dies of first silicon wafer 1500 in die-to-wafer bonding 1518. Note that not all memory dies that are bonded to first silicon wafer 1500 have to be from second silicon wafer 1510 (e.g., memory dies that are bonded to a single control wafer or a single control die may come from multiple memory wafers). Subsequent to die-to-wafer bonding 1518, first silicon wafer 1500 may be scribed to divide individual integrated memory assemblies.

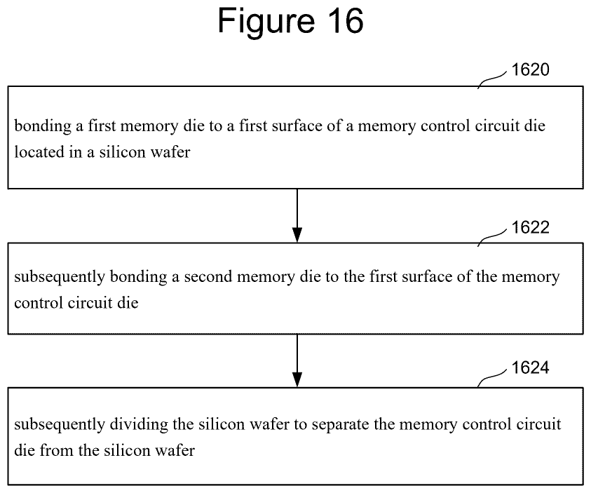

FIG. 16 shows an example of a method according to an example of the present technology. The method includes bonding a first memory die to a first surface of a control die located in a silicon wafer 1620, subsequently bonding a second memory die to the first surface of the control die 1622; and subsequently dividing the silicon wafer to separate the control die from the silicon wafer 1624.

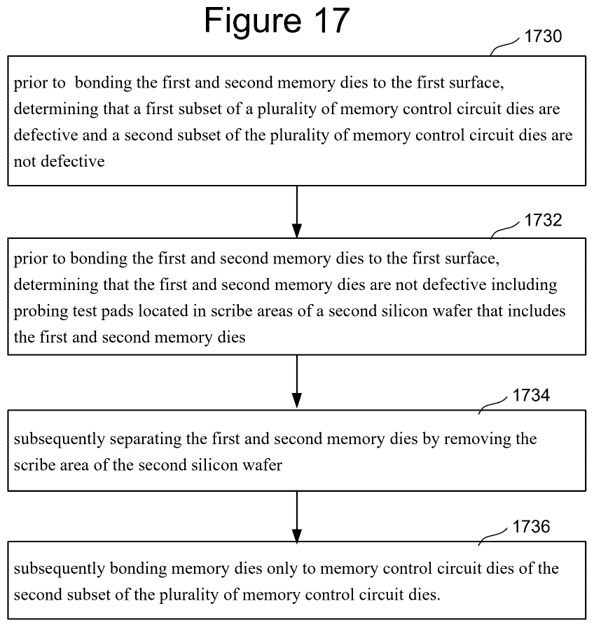

FIG. 17 shows an example of a method according to an example of the present technology. The method includes prior to bonding the first and second memory dies to the first surface, determining that a first subset of a plurality of control dies are defective and a second subset of the plurality of control dies are not defective 1730, prior to bonding the first and second memory dies to the first surface, determining that the first and second memory dies are not defective including probing test pads located in scribe areas of a second silicon wafer that includes the first and second memory dies 1732, subsequently separating the first and second memory dies by removing the scribe area of the second silicon wafer 1734 (e.g., as shown in FIG. 14A-C) and subsequently bonding memory dies only to control dies of the second subset of the plurality of control dies 1736.

An example of an apparatus includes a silicon wafer and a plurality of memory dies. The silicon wafer includes a plurality of control dies, each control die having first bond pads on a first surface of the control die. The plurality of memory dies each has second bond pads on a second surface facing the first surface of the control die. The second bond pads of each memory die are bonded to corresponding first bond pads on the first surface of the memory control circuit.

The first surface of the control die may include a plurality of slots, each slot including a plurality of first bond pads connected, each slot occupying an area on the first surface that is equal to or greater than the area of the second surface of the memory die. Each slot may include first bond pads connected to word line driver circuits and bit line driver circuits of the control die. One or more of the plurality of slots may not be occupied by a memory dic. The plurality of memory dies may include a first memory die of a first type and a second memory die of a second type that is different to the first type. The first memory die may have a first number of layers of word lines and the second memory die may have a second number of layers of word lines that is greater than the first number. The first memory die may have nonvolatile memory cells configured to store a first number of bits per cell, the second memory die may have nonvolatile memory cells configured to store a second number of bits per cell and the second number is greater than the first number. The plurality of memory dies may be formed in a second silicon wafer, the second silicon wafer including scribe areas separating the plurality of memory dies; and probe pads located in the scribe areas, the probe pads electrically connected to components of memory arrays formed in the plurality of memory dies. Each of the plurality of memory dies may include a 3D NAND memory array that includes a plurality of word line layers.

An example of a method includes bonding a first memory die to a first surface of a control die located in a silicon wafer; subsequently bonding a second memory die to the first surface of the control die; and subsequently dividing the silicon wafer to separate the control die from the silicon wafer.

The control die may include a plurality of slots, bonding the first memory die to the first surface of the memory control circuit may include aligning the first memory die with a first slot and bonding the second memory die to the first surface of the memory control circuit may include aligning the second memory die with a second slot. In an example, each slot includes a plurality of first bond pads, aligning the first memory die with the first slot includes aligning corresponding second bond pads of the first memory die with first bond pads of the first slot and aligning the second memory die with the second slot includes aligning corresponding second bond pads of the second memory die with first bond pads of the second slot. In an example, the first memory die is not identical to the second memory die. In an example, the first memory die and the second memory die have at least one of: different numbers of word line levels and/or different numbers of bits per cell. In an example the method further includes prior to bonding the first and second memory dies to the first surface, determining that the control die is not defective. In an example the method further includes prior to bonding the first and second memory dies to the first surface, determining that a first subset of the plurality of control dies are defective and a second subset of the plurality of control dies are not defective; and subsequently bonding memory dies only to control dies of the second subset of the plurality of control dies. In an example, the method further includes prior to bonding the first and second memory dies to the first surface, determining that the first and second memory dies are not defective. In an example, determining that the first and second memory dies are not defective includes probing probe pads located in scribe areas of a second silicon wafer that includes the first and second memory dies and subsequently separating the first and second memory dies by removing the scribe areas of the second silicon wafer.

An example of a memory system includes a control die that includes word line drivers connected to word line bond pads and bit line drivers connected to bit line bond pads on a first surface of the control die, the word line bond pads and bit line bond pads arranged in a plurality of slots, each slot sized to accommodate a corresponding memory die and each slot having word line bond pads and bit line bond pads; a plurality of memory dies bonded to the control die including at least a first memory die located at a first slot and a second memory die located at a second slot, word lines of the first and second memory dies connected to word line bond pads and bit lines of the first and second memory dies connected to bit line bond pads of respective first and second slots; and at least one empty slot that has word line bond pads and bit line bond pads that are not bonded.

In an example, the first memory die and the second memory die are different in at least one of: respective numbers of word line layers, respective numbers of bits per cell and/or respective data capacities.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
a silicon wafer that includes a plurality of control dies, each control die having first bond pads on a first surface of the control die; and
a plurality of memory dies, each memory die having second bond pads on a second surface of the memory die, the second surface of each memory die facing the first surface of the control die and the second bond pads of each memory die bonded to corresponding first bond pads on the first surface of the memory control circuit.

2. The apparatus of claim 1, wherein the first surface of the control die includes a plurality of slots, each slot including a plurality of first bond pads connected, each slot occupying an area on the first surface that is equal to or greater than the area of the second surface of the memory die.

3. The apparatus of claim 2, wherein each slot includes first bond pads connected to word line driver circuits and bit line driver circuits of the control die.

4. The apparatus of claim 2, wherein one or more of the plurality of slots is not occupied by a memory die.

5. The apparatus of claim 1, wherein the plurality of memory dies includes a first memory die of a first type and a second memory die of a second type that is different to the first type.

6. The apparatus of claim 5, wherein the first memory die has a first number of layers of word lines and the second memory die has a second number of layers of word lines that is greater than the first number.

7. The apparatus of claim 5, wherein the first memory die has nonvolatile memory cells configured to store a first number of bits per cell, the second memory die has nonvolatile memory cells configured to store a second number of bits per cell and the second number is greater than the first number.

8. The apparatus of claim 1, wherein the plurality of memory dies are formed in a second silicon wafer, the second silicon wafer including scribe areas separating the plurality of memory dies; and
probe pads located in the scribe areas, the probe pads electrically connected to components of memory arrays formed in the plurality of memory dies.

9. The apparatus of claim 1, wherein each of the plurality of memory dies includes a 3D NAND memory array that includes a plurality of word line layers.

10. A method comprising:
bonding a first memory die to a first surface of a control die located in a silicon wafer;
subsequently bonding a second memory die to the first surface of the control die; and
subsequently dividing the silicon wafer to separate the control die from the silicon wafer.

11. The method of claim 10, wherein the control die includes a plurality of slots, bonding the first memory die to the first surface of the memory control circuit includes aligning the first memory die with a first slot and bonding the second memory die to the first surface of the memory control circuit includes aligning the second memory die with a second slot.

12. The method of claim 11, wherein each slot includes a plurality of first bond pads, aligning the first memory die with the first slot includes aligning corresponding second bond pads of the first memory die with first bond pads of the first slot and aligning the second memory die with the second slot includes aligning corresponding second bond pads of the second memory die with first bond pads of the second slot.

13. The method of claim 10, wherein the first memory die is not identical to the second memory die.

14. The method of claim 13, wherein the first memory die and the second memory die have at least one of: different numbers of word line levels and/or different numbers of bits per cell.

15. The method of claim 10, further comprising:
prior to bonding the first and second memory dies to the first surface, determining that the control die is not defective.

16. The method of claim 15, wherein the silicon wafer includes a plurality of control dies, further comprising:
prior to bonding the first and second memory dies to the first surface, determining that a first subset of the plurality of control dies are defective and a second subset of the plurality of control dies are not defective; and
subsequently bonding memory dies only to control dies of the second subset of the plurality of control dies.

17. The method of claim 10, further comprising:
prior to bonding the first and second memory dies to the first surface, determining that the first and second memory dies are not defective.

18. The method of claim 17, wherein determining that the first and second memory dies are not defective includes probing probe pads located in scribe areas of a second silicon wafer that includes the first and second memory dies and subsequently separating the first and second memory dies by removing the scribe areas of the second silicon wafer.

19. A memory system comprising:
a control die that includes word line drivers connected to word line bond pads and bit line drivers connected to bit line bond pads on a first surface of the control die, the word line bond pads and bit line bond pads arranged in a plurality of slots, each slot sized to accommodate a corresponding memory die and each slot having word line bond pads and bit line bond pads;
a plurality of memory dies bonded to the control die including at least a first memory die located at a first slot and a second memory die located at a second slot, word lines of the first and second memory dies connected to word line bond pads and bit lines of the first and second memory dies connected to bit line bond pads of respective first and second slots; and
at least one empty slot that has word line bond pads and bit line bond pads that are not bonded.

20. The memory system of claim 19, wherein:
the first memory die and the second memory die are different in at least one of: respective numbers of word line layers, respective numbers of bits per cell and/or respective data capacities.
